(19) United States
(12) Patent Application Publication
(10) Pub. No.: US 2024/0015932 A1
(43) Pub. Date: Jan. 11, 2024

(54) COMPOSITE THERMAL CONTROL SUBSTRATE

(71) Applicant: Derek Simkowiak, Lynnwood, WA (US)

(72) Inventor: Derek Simkowiak, Lynnwood, WA (US)

(73) Assignee: Holding Zero, LLC, Albuquerque, NM (US)

(21) Appl. No.: 18/349,683

(22) Filed: Jul. 10, 2023

Related U.S. Application Data
(60) Provisional application No. 63/359,237, filed on Jul. 8, 2022.

(51) Int. Cl. H05K 7/20

(52) U.S. Cl. CPC H05K 7/2039

(57) ABSTRACT

A composite thermal control substrate for heating and cooling printed circuit boards (PCBs), or other temperature-sensitive equipment, which thermally connects said equipment to a single thermally conductive surface plane, while maintaining electrical isolation of the equipment and its components. The thermally conductive surface plane provides a large, uniform, flat, exposed thermal control surface which can be connected to industrial thermal control systems, such as heat sinks, air or liquid heat exchangers, thermoelectric cooling systems, or heating elements. This provides a substantially large and efficient heat collection and dissipation surface area, and more thermal mass, providing increased thermal stability and flexibility in the design and application of external heating or cooling systems for PCBs or other temperature-sensitive equipment. Furthermore, the composite thermal control substrate is manufactured and applied separately from the panel-based PCB manufacturing process.

### CROSS-REFERENCE TO RELATED APPLICATIONS

This application claims the benefit of U.S. Provisional Patent Application Ser. No. 63/359,237 filed Jul. 8, 2022, titled “COMPOSITE THERMAL CONTROL SUBSTRATE,” and the subject matter thereof is incorporated herein by reference thereto.

### TECHNICAL FIELD

The present disclosure relates to a thermal control system. More particularly, the present disclosure relates to structural, thermal, and electrical aspects of a composite thermal control substrate.

### BACKGROUND ART

Components mounted to printed circuit boards (PCBs) generate excess heat during operation. Components such as central processing units (CPUs), graphics processing units (GPUs), random access memory (RAM), power management integrated circuits (PMICs), and power supplies can generate sufficient excess heat as to a require a cooling system to maintain normal operation.

In addition to cooling waste heat, some operating environments require supplemental PCB heating to maintain normal operation. For example, PCBs in deep sea ROVs, space satellites, or Arctic conditions may require supplemental heating to maintain minimum operating temperature. Furthermore, many sensitive electronic sensors used in scientific applications require a stable temperature for reliable data collection, which may require both heating and cooling to counteract a varying temperature in the operating environment.

The necessity to maintain electrical isolation from the thermal control system, in order to avoid electrically shorting the exposed electrical contacts of PCB components having varied geometric shapes and vertical heights, substantially limits the thermal control surfaces available for PCBs. Additionally, the intrinsic thermal characteristics of a PCB are permanently fixed once manufactured, because the geometric layout of the temperature-sensitive components is fixed once they are soldered to the PCB or other temperature-sensitive equipment. Thus, a thermal control system is required which reduces or removes one or more of the issues mentioned. The present invention seeks to overcome the limitations and shortcomings contained in the prior art.

None of the prior art fully addresses the problems resolved by the present invention. The present invention overcomes these limitations contained in the prior art.

Certain embodiments of the invention have other steps or elements in addition to or in place of those mentioned above. The steps or element will become apparent to those skilled in the art from a reading of the following detailed description when taken with reference to the accompanying figures, if any

### BRIEF DESCRIPTION OF THE SEVERAL VIEWS OF THE DRAWINGS

FIG. 1 illustrates an exploded view of the composite thermal control substrate, according to certain embodiments of the invention.

FIG. 2 illustrates a side view of the composite thermal control substrate, according to certain embodiments of the invention.

FIG. 3 illustrates a side view detail of the inner bonding layer, according to certain embodiments of the invention.

FIG. 4 illustrates a method of assembling composite thermal control substrate, according to certain embodiments of the invention.

### DETAILED DESCRIPTION OF THE INVENTION

The best mode for carrying out the invention will be described herein. The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. To avoid obscuring the present invention, some well-known system configurations, and process steps are not disclosed in detail. The figures illustrating embodiments of the system, if any, are semi-diagrammatic and not to scale and, particularly, some of the dimensions are for the clarity of presentation and are shown exaggerated in the drawing figures.

Alternate embodiments have been included throughout, and the order of such are not intended to have any other significance or provide limitations for the present invention.

For expository purposes, the term “horizontal” as used herein is defined as a plane parallel to the plane or surface of the present apparatus, regardless of its orientation. The term “vertical” refers to a direction perpendicular to the horizontal as just defined. Terms, such as “above”, “below”, “bottom”, “top”, “side”, “higher”, “lower”, “upper”, “over”, and “under”, are defined with respect to the horizontal plane, as shown in the figures, if any. The term “on” means that there is direct contact among elements.

The words “including”, “comprising”, “incorporating”, “consisting of”, “have”, and “is” are meant to be non-exclusive, meaning additional items, components or elements may be present. Joinder references such as “connected”, “connecting”, and “coupled” do not limit the position, orientation, or use of systems and/or methods, and do not necessarily infer that two elements are directly connected. All identifying numerical terms are for identification only, and do not refer to the order or preference of any element, embodiment, variation and/or modification.

The present disclosure provides a composite thermal control substrate, comprising a metal plane layer comprised of one or more metal alloys which may be roll bonded, electrically plated, diffusion bonded, or fused; an outer bonding layer; a coupling layer; an inner bonding layer; and an electrically insulating layer.

The present disclosure provides a method of assembling a composite thermal control substrate, comprising roll bonding, electrically plating, diffusion bonding, or fusing a plurality of metal alloy layers into a single metal plane layer, or selecting a previously bonded metal alloy for a metal plane layer; positioning a metal plane layer; positioning an outer bonding layer; coupling the outer bonding layer to the metal plane layer; positioning a coupling layer; coupling the coupling layer to the outer bonding layer; positioning an inner bonding layer; coupling the inner bonding layer to the coupling layer; positioning an electrically insulating layer; and coupling the electrically insulating layer to the inner bonding layer.

The present disclosure provides a composite thermal control substrate for heating and cooling PCBs, or other temperature-sensitive equipment, which thermally connects said equipment to a single thermally conductive surface plane, while maintaining electrical isolation of the equipment and its components. The thermally conductive surface plane provides a large, uniform, flat, exposed thermal control surface which can be connected to industrial thermal control systems, such as heat sinks, air or liquid heat exchangers, thermoelectric cooling systems, or heating elements. This provides a substantially large and efficient heat collection and dissipation surface area, and more thermal mass, providing increased thermal stability and flexibility in the design and application of external heating or cooling systems for PCBs or other temperature-sensitive equipment.

Furthermore, the composite thermal control substrate is manufactured and applied separately from the panel-based PCB manufacturing process. The thermal control surface can be applied to pre-existing PCB designs post hoc manufacturing, and integrated into a packaging solution, which allows adaptation and extension of a PCB's intrinsic thermal characteristics. The present invention can be used to adapt existing electronics to harsh or unexpected environments, or to connect generic industrial thermal management infrastructure to temperature-sensitive equipment.

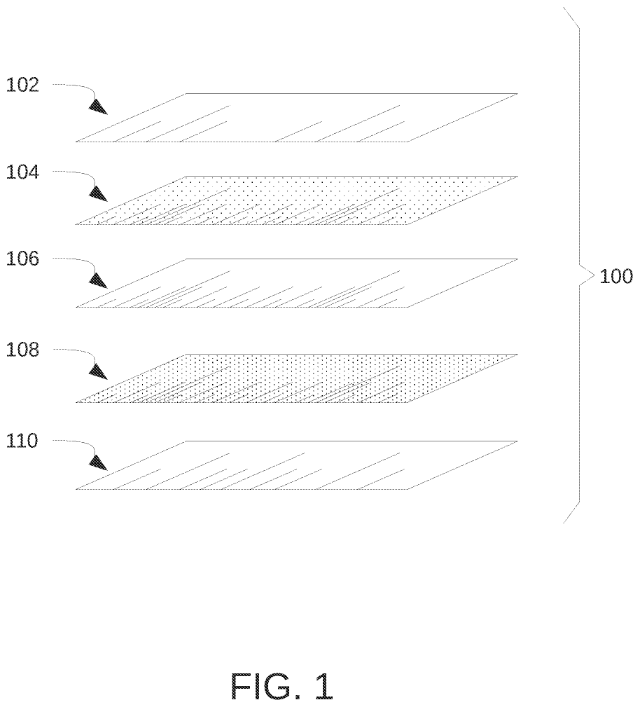

FIG. 1 illustrates an exploded view of the composite thermal control substrate 100, according to certain embodiments of the invention. The composite layers are comprised of the metal plane layer 102, outer bonding layer 104, coupling layer 106, inner bonding layer 108, and the electrically insulating layer 110, from outermost to innermost respectively. The outermost metal plane layer 102 is exposed for thermal control and management, and the innermost electrically insulating layer 110 makes thermal contact with the PCB.

The outermost layer is the metal plane layer 102. The metal plane layer 102 is a flat plane of one or more layers of bonded metal alloys. The metal alloys are selected for substantial thermal conductivity.

In the preferred embodiment, the metal plane layer 102 consists of a uniform sheet of an Aluminum alloy. In other embodiments, the specific composition of the metal plane layer 102 is selected to meet the operating requirements for thermal conductivity, cost, mass, strength, stiffness, reflectivity, and radiation protection in the intended operating environment, as would be known to those of skill in the art. For example, a Copper or Silver alloy may be used in environments where greater thermal conductivity per unit volume is needed, but a Gold alloy may be used where greater solar reflectivity is needed. An electroplated Nickel alloy layer may be applied to provide corrosion protection, and a Lead alloy may be included to provide radiation protection. Multiple metal alloys may be roll bonded, electrically plated, diffusion bonded, or fused, as would be known to those of skill in the art, to comprise the metal plane layer 102.

The next outermost layer is the outer bonding layer 104, which connects the metal plane layer 102 with the coupling layer 106. The bonding layer provides bonding, thermal coupling, and shear protection between the metal plane layer 102 and the coupling layer 106.

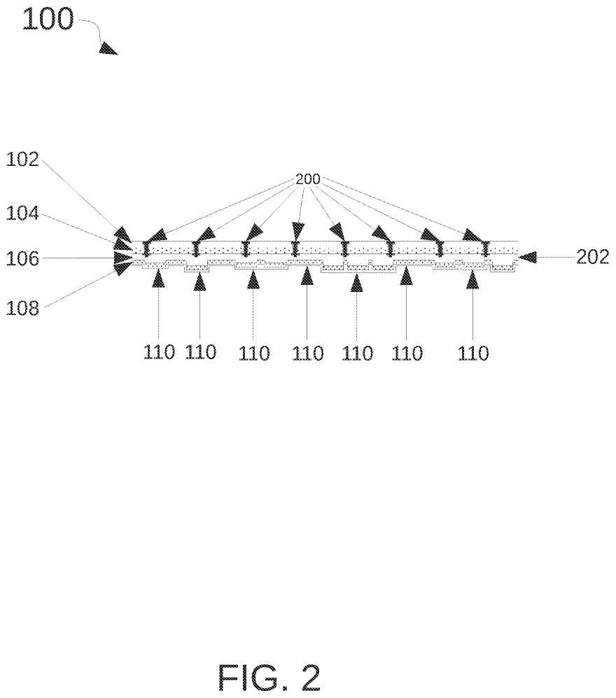

FIG. 2 illustrates a side view of the composite thermal control substrate, according to certain embodiments of the invention. In the preferred embodiment, the outer bonding layer 104 is comprised of an adhesive film. In other embodiments, the outer bonding layer 104 is a diffusion bonded metal alloy. In some embodiments, fasteners 200 may be used to fasten the outer bonding layer 104 to the metal plane layer 102 and the coupling layer 106.

The next outermost layer is the coupling layer 106. The coupling layer 106 is a form-fitted layer which is topographically matched to the varying surface heights of the PCB or other temperature-sensitive equipment for which the composite thermal control substrate 100 is used. The coupling layer 106 maximizes the surface area contact with temperature-sensitive components and the outermost layer of the PCB or other temperature-sensitive equipment, while providing a substantially efficient thermal path to the metal plane layer 102. In the preferred embodiment, the coupling layer 106 is comprised of an Aluminum alloy 202.

The next outermost layer is the inner bonding layer 108, which connects the coupling layer 106 to the electrically non-conducting material of the electrically insulating layer 110.

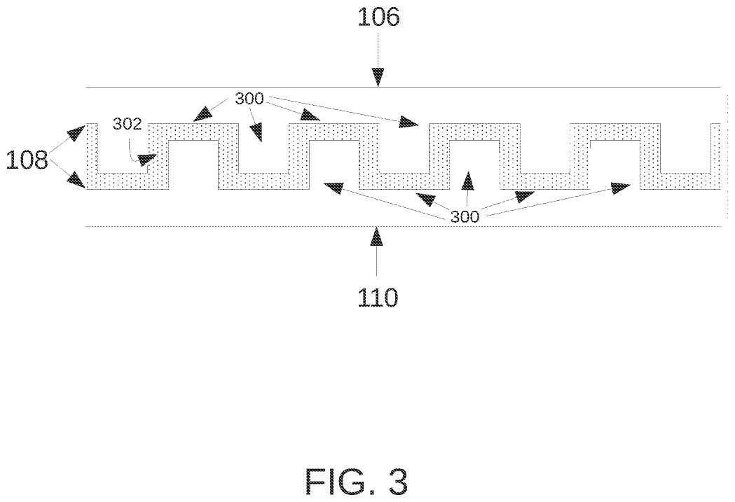

FIG. 3 illustrates a side view detail of the inner bonding layer 108, according to certain embodiments of the invention. In the certain embodiments, an interconnecting geometric pattern 300 is used to provide structural integrity, shear prevention, and increased surface contact area within the inner bonding layer 108. In other embodiments, the interconnecting geometric pattern 300 is omitted. In certain embodiments, the inner bonding layer 108 may be comprised of an adhesive film 302.

The next outermost layer is the electrically insulating layer 110. The electrically insulating layer 110 makes thermal contact with the PCB and exposed PCB components, or other temperature-sensitive equipment. The electrically insulating layer 110 provides electrical isolation between the outer composite thermal control substrate 100 and the PCB. The electrically insulating layer 110 provides sufficient electrical insultation to prevent the maximum operating voltage on the PCB or other temperature-sensitive equipment from crossing the electrically insulating layer 110 to the coupling layer 106. In the preferred embodiment, the electrically insulating layer 110 consists of a Silicone-based material. In another embodiment, the electrically insulating layer 110 consists of an electrically non-conductive polymer.

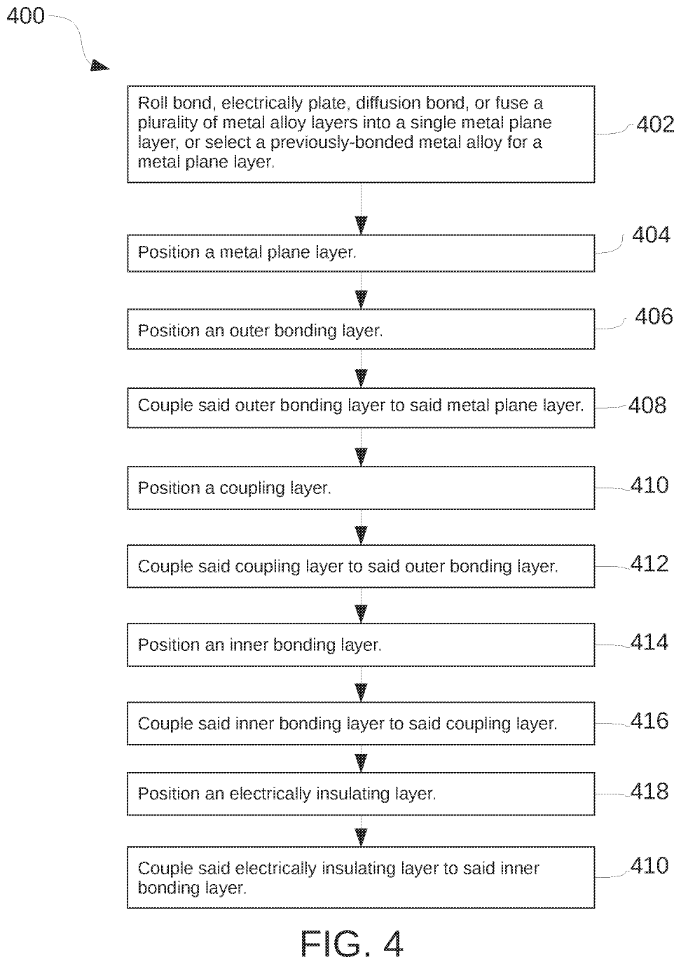

FIG. 4 illustrates a method of assembling a composite thermal control substrate 100, according to certain embodiments.

According to method 400, at step 402 a plurality of metal alloy layers are roll bonded, electrically plated, diffusion bonded, or fused into a single metal plane layer, as would be known to those of skill in the art, or a previously-bonded metal alloy is selected, for a metal plane layer 102.

According to method 400, at step 404 a metal plane layer 102 is positioned. At step 406 an outer bonding layer 104 is positioned, and at step 408 said outer bonding layer 104 is coupled to said metal plane layer 102.

According to method 400, at step 410 a coupling layer 106 is positioned, and at step 412 said coupling layer 106 is coupled to said outer bonding layer 104. At step 414 an inner bonding layer 108 is positioned, and at step 416 said inner bonding layer 108 is coupled to said coupling layer 106.

According to method 400, at step 418 an electrically insulating layer 110 is positioned, and at step 420 said electrically insulating layer 110 is coupled to said inner bonding layer 108.

For steps 404, 406, 410, 414, and 418 of method 400, in which a substrate layer is positioned, said substrate layers may be positioned though a computer-assisted mechanism, as would be known to those skilled in the art, to use a datum on said substrate layers to achieve substantially accurate alignment.

The best mode for carrying out the invention has been described herein. The previous embodiments are described in sufficient detail to enable those skilled in the art to make and use the invention. It is to be understood that other embodiments would be evident based on the present disclosure, and that system, process, or mechanical changes may be made without departing from the scope of the present invention.

In the previous description, numerous specific details and examples are given to provide a thorough understanding of the invention. However, it will be apparent that the invention may be practiced without these specific details and specific examples. While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations that fall within the scope of the included claims. All matters previously set forth herein or shown in the accompanying figures are to be interpreted in an illustrative and non-limiting sense.

### LIST OF ELEMENTS SHOWN ON THE DRAWINGS

100 Composite thermal control substrate
102 Metal plane layer
104 Outer bonding layer
106 Coupling layer
108 Inner bonding layer
110 Electrically insulating layer
200 Fasteners
202 Aluminum alloy
300 Interconnecting geometric pattern
302 Adhesive film
400 Method
402 Step
404 Step
406 Step
408 Step
410 Step
412 Step
414 Step
416 Step
418 Step
420 Step

What is claimed is:

1. A composite thermal control substrate, comprising:
a metal plane layer comprised of one or more metal alloys which may be roll bonded, electrically plated, diffusion bonded, or fused;
an outer bonding layer;
a coupling layer;
an inner bonding layer; and
an electrically insulating layer.

2. The composite thermal control substrate of claim 1, wherein the metal plane layer is comprised of an aluminum alloy.

3. The composite thermal control substrate of claim 1, wherein the outer bonding layer is comprised of an adhesive film.

4. The composite thermal control substrate of claim 1, wherein the outer bonding layer is comprised of a diffusion bonded metal alloy.

5. The composite thermal control substrate of claim 1, wherein the outer bonding layer includes fasteners.

6. The composite thermal control substrate of claim 1, wherein the coupling layer is comprised of an aluminum alloy.

7. The composite thermal control substrate of claim 1, wherein the inner bonding layer has an interconnecting geometric pattern, such that structural integrity, shear prevention, and surface contact area are increased within the inner bonding layer.

8. The composite thermal control substrate of claim 1, wherein the inner bonding layer consists of an adhesive film.

9. The composite thermal control substrate of claim 1, wherein the electrically insulating layer consists of a silicone-based material.

10. The composite thermal control substrate of claim 1, wherein the electrically insulating layer consists of an electrically non-conductive polymer.

11. A method of assembling a composite thermal control substrate, comprising:
roll bonding, electrically plating, diffusion bonding, or fusing a plurality of metal alloy layers into a single metal plane layer, or selecting a previously bonded metal alloy for a metal plane layer;
positioning a metal plane layer;
positioning an outer bonding layer;
coupling the outer bonding layer to the metal plane layer;
positioning a coupling layer;
coupling the coupling layer to the outer bonding layer;
positioning an inner bonding layer;
coupling the inner bonding layer to the coupling layer;
positioning an electrically insulating layer; and
coupling the electrically insulating layer to the inner bonding layer.
